(19) United States
(12) Patent Application Publication
(10) Pub. No.: US 2009/0269182 A1
(43) Pub. Date: Oct. 29, 2009

(54) CONTAINER FOR STORING PLATES FOR ELECTRONIC CIRCUITS AND RELATIVE METHOD

(75) Inventor: Andrea BACCINI, San Biagio di Callalta (TV) (IT)

Correspondence Address: HAMRE, SCHUMANN, MUELLER & LARSON, P.C., P.O. BOX 2902, MINNEAPOLIS, MN, 55402-0902, US

(73) Assignee: APPLIED MATERIALS BACCINI SPA CON SOCIO UNICO, San Biagio di Callalta (TV) (IT)

(21) Appl. No.: 12/257,456

(22) Filed: Oct. 24, 2008

(30) Foreign Application Priority Data
Oct. 24, 2007 (IT) UD2007A000202

(51) Int. Cl. H01L 21/673; B65D 85/86

(52) U.S. Cl. 414/800; 206/706

(57) ABSTRACT

A container for storing plates for electronic circuits, able to be used in an automatic store, comprises a supporting base provided with a first face defining a supporting plane and a second face defining a storage plane. The container has at least a portion of wall, disposed in correspondence with one side of the supporting base, converging in a first corner of the supporting base and cooperating with holding elements present in an adjacent side and defining respectively a first abutment plane and a second abutment plane substantially orthogonal with each other and with the supporting plane.

### FIELD OF THE INVENTION

The present invention concerns a container for storing plates for electronic circuits with a defined geometric shape as well as the method for its use.

In particular, the container is able to be employed in an automatic store for storing plates for electronic circuits, such as, preferably but not exclusively, wafers, for example silicon based or alumina based, in particular for photovoltaic cells or for green-tape type circuits, classified according to quality production classes after a quality test performed with a specific testing unit.

### BACKGROUND OF THE INVENTION

A container for storing plates for electronic circuits is known, able to be employed in an automatic store, with a substantially square base and provided with walls with a predefined height and thickness that rise in correspondence with the sides of said base which also defines a plane orthogonal to the plane defined by said walls.

One disadvantage of the known container is that one or more of the plates stacked on this base, during the movement of the container inside the automatic store, can move inside the container, coming out of line with respect to the others, with the risk of achieving an irregular storing of the plates with the consequent problems for possible subsequent packing steps.

Another disadvantage derives from the lack of identification, by means of automatic systems, of the material or of the quality level present in, or characteristic of, the container or of the plates placed on the support.

Another problem is the stacking of the containers for store purposes and the risk that the stack may fall, causing damage and interrupting the automatic functioning cycle.

A further problem is the need to make a container that is light but at the same time structurally stable.

One purpose of the present invention is to achieve a container for storing plates for electronic circuits that allows to achieve a regular storage of the plates, so that the stacked plates are always aligned and positioned in the desired manner.

Another purpose of the present invention is to achieve a container that allows to identify the product and/or the quality level of the plates located in the container.

A further purpose is to achieve a container that, stacked on other analogous containers, does not cause the stack to collapse.

Another purpose is to achieve a light and structurally stable container.

The Applicant has devised, tested and embodied the present invention to overcome the shortcomings of the state of the art and to obtain these and other purposes and advantages.

### SUMMARY OF THE INVENTION

The present invention is set forth and characterized in the independent claims, while the dependent claims describe other characteristics of the invention or variants to the main inventive idea.

In accordance with the above purposes, a container for storing plates for electronic circuits, able to be employed in an automatic store, comprises a supporting base, provided with a first face defining a supporting plane and with a second face defining a storage plane.

According to a first inventive idea, the container has at least two portions of wall, disposed in correspondence with two adjacent sides of the supporting base, converging in a corner of the supporting base and defining respectively a first abutment plane and a second abutment plane substantially orthogonal with each other and with the supporting plane.

According to a characteristic feature of the present invention the storage plane is inclined with respect to the supporting plane.

According to an advantageous feature of the present invention the storage plane is inclined in the direction of said corner.

In this way the plates that are positioned inside the container are stacked in a regular manner since they slide in the direction of said corner and move close to said walls, conforming their position both with respect to the container, and also with respect to the other plates.

According to a further inventive idea, the portions of wall are disposed parallel and at the opposite sides of the storage plane. Said walls define abutment planes substantially orthogonal to the supporting plane. In this variant the storage plane is inclined with respect to the supporting plane and towards one of said walls, or towards an edge of one of said walls. Possible means may be present to intercept the compartment between one wall and the other and thus hold the plates in position.

According to another advantageous feature of the present invention, the supporting base is provided with a seating able to contain means to identify the plates stacked in said container. Said identification means allows to control the container and/or the plates and/or the quality level thereof.

The container also has structural stiffening means. A first inventive idea provides suitable ribs present in the lower part of the container. Said inventive idea can provide ferromagnetic means located in suitable positions, or holes able to cooperate with pin elements present in the lower container.

According to a variant, the supporting base of the container is provided with a reinforcement plate, made of ferromagnetic material, so as to confer structural rigidity on the container.

According to a further advantageous feature of the present invention said walls of the container comprise magnetic elements or pin elements. In this way, when the storage containers are stacked inside the automatic store, the elements present in the walls of the container cooperate with the corresponding stacking or solidarity means present in the upper container.

### BRIEF DESCRIPTION OF THE DRAWINGS

These and other characteristics of the present invention will become apparent from the following description of a preferential form of embodiment, given as a non-restrictive example with reference to the attached drawings wherein:

FIG. 1 is a schematic view from above of a container according to the present invention;

FIG. 2 is a first schematic side view of the device in FIG. 1;

FIG. 3 is a second schematic side view of the device in FIG. 1.

### DETAILED DESCRIPTION OF A PREFERENTIAL FORM OF EMBODIMENT

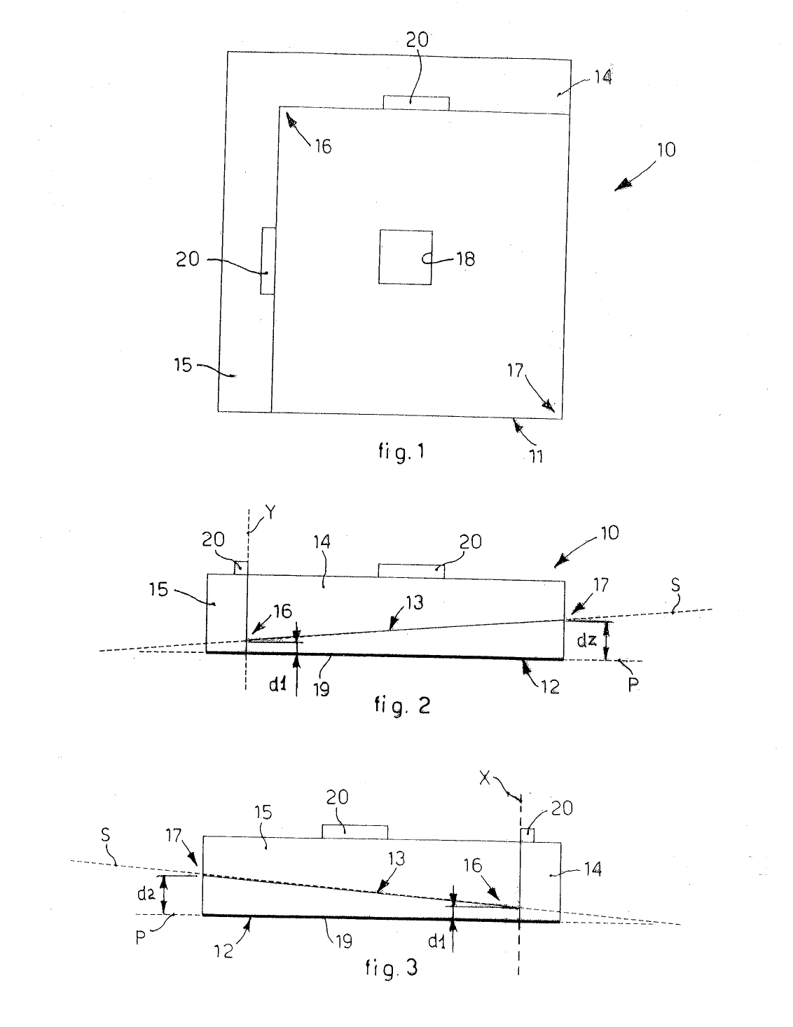

With reference to FIG. 1, a container 10 for storing plates for electronic circuits, such as, preferably but not exclusively wafers, for example silicon based or alumina based, in particular for photovoltaic cells or for green-tape type circuits, classified according to quality production classes after a quality test performed with a specific testing unit, is able to be employed in an automatic store.

The container 10 comprises a supporting base 11, substantially square in shape, with a predefined thickness, provided with a first face 12 defining a supporting plane P, and with a second face 13 defining a storage plane S. The container 10 also comprises a first wall 14 which rises in correspondence with a first side of the supporting base 11 and a second wall 15, which rises in correspondence with a second side of the supporting base 11, adjacent to said first side. The walls 14, 15 converge in a first corner 16 of the supporting base 11 and define respectively a first plane X and a second plane Y, orthogonal with respect to each other and orthogonal to the supporting plane P.

The storage plane S is inclined with respect to the first plane X, to the second plane Y and to the supporting plane P, in the direction of the first corner 16.

In correspondence with the first corner 16 the distance d1 between the supporting plane P and the storage plane S is less than the distance d2 between said two planes in correspondence with a second corner 17 of the supporting base 11, opposite the corner 16.

The supporting base 11 is provided with a seating 18, inside which identification means is able to be disposed, containing information relating to the plates located in the container 10. Advantageously the identification means comprises an electronic chip in which information relating, for example, to the quality, quantity, type and the technical characteristics of the plates stored in the container 10 is memorized.

The identification means is able to be implemented each time with provided data, as well as to be recognized by corresponding recognition means, for example of the radio frequency type, with magnetic induction, or other, disposed in the work lines and/or inside the automatic store. In this way, on the basis of the information detected by the recognition means, the container is suitably stored, selected and put to work, on the basis of the quality, and/or type, and/or the technical characteristics of the plates present in the container 10.

The container 10 also comprises a reinforcement plate 19 associated with the first face 12, made of ferromagnetic material, so as to confer a structural rigidity on the container.

Moreover, the container 10 is provided with magnetic elements, not shown in the drawings, disposed on the upper surface of the walls 14, 15 in correspondence with the zone where the walls 14, 15 converge.

According to a variant of the present invention the magnetic elements are able to be disposed at the ends of the walls 14, 15.

When several containers 10 are stacked inside the automatic store, the magnetic elements cooperate with the reinforcement plate of the container above, in order to guarantee stability to the stack of containers 10, preventing them from collapsing in correspondence with the second corner 17.

The container 10 also comprises ribs 20, made in correspondence with the upper surface of each of the walls 14, 15, which allow several containers 10 that have to be stacked to be placed exactly one on top of the other, also facilitating the action of said magnetic elements. The ribs 20 are able to be inserted into corresponding seatings made in the reinforcement plate 19 and not shown in the drawings.

It is clear that modifications and/or additions of parts may be made to the container for storing plates for electronic circuits as described heretofore, without departing from the field and scope of the present invention.

It is also clear that, although the present invention has been described with reference to some specific examples, a person of skill in the art shall certainly be able to achieve many other equivalent forms of container for storing plates for electronic circuits, having the characteristics as set forth in the claims and hence all coming within the field of protection defined thereby.

1. A container for storing plates for electronic circuits, able to be used in an automatic store, comprising a supporting base provided with a first face defining a supporting plane (P) and a second face defining a storage plane (S), the container having at least a portion of wall, disposed in correspondence with one side of said supporting base, converging in a first corner of said supporting base and cooperating with holding means present in an adjacent side and defining respectively a first abutment plane (X) and a second abutment plane (Y) substantially orthogonal with each other and with said supporting plane (P).

2. A container as in claim 1, wherein the holding means consists of at least a portion of wall.

3. A container as in claim 1, wherein said storage plane (S) is inclined with respect to the supporting plane (P).

4. A container as in claim 1, wherein the storage plane (S) is inclined in the direction of the first corner.

5. A container as in claim 1, wherein the portions of wall are located parallel and on opposite sides of said storage plane (S).

6. A container as in claim 1, wherein the walls define abutment planes (X, Y) substantially orthogonal to the supporting plane (P).

7. A container as in claim 1, wherein the storage plane (S) is inclined with respect to the supporting plane (P) and towards one of the walls.

8. A container as in claim 7, wherein a means is present to intercept the compartment between the walls.

9. A container as in claim 1, wherein said supporting base is provided with a seating able to contain means to identify said plates.

10. A container as in claim 9, wherein the identification means can be re-written and read.

11. A container as in claim 1, having structural stiffening means.

12. A container as in claim 11, wherein the structural stiffening means comprises first ribs disposed in the lower part of said container.

13. A container as in claim 11, wherein the structural stiffening means comprises ferromagnetic means.

14. A container as in claim 13, wherein the ferromagnetic means comprises a plate.

15. A container as in claim 11, wherein the structural stiffening means comprises pin elements able to cooperate with corresponding hole elements.

16. A container as in claim 1, wherein the walls are provided with magnetic elements.

17. A container as in claim 16, wherein the magnetic elements are disposed in correspondence with the first corner.

18. A container as in claim 17, wherein the magnetic elements are disposed at the ends of the walls.

19. A container as in claim 1, wherein the walls comprise stacking elements.

20. A container as in claim 1, wherein the stacking elements comprise second ribs made in correspondence with said walls.

21. A container as in claim 1, wherein the second ribs are disposed on the upper surface of the walls.

22. A method for storing plates for electronic circuits in an automatic store, comprising at least:
a step in which said plates are disposed inside a container provided with identification means;
a step in which said identification means acquires information relating to said plates;
a step in which recognition means recognize said identification means; and
a step in which said container is sent to subsequent working steps according to said information from said identification means.
